(19) United States
(12) Patent Application Publication
(10) Pub. No.: US 2026/0040830 A1
(43) Pub. Date: Feb. 5, 2026

(54) PIEZOELECTRIC MATERIALS AND RELATED DEVICES FOR ACOUSTIC SENSOR APPLICATIONS

(71) Applicant: Robert Bosch Gmbh, Stuttgart (DE)

(72) Inventors: Mordechai KORNBLUTH, Brighton, MA (US); Daniel PANTEL, Mundelsgheim (DE); Simon SCHNEIDER, Karlsruhe (DE)

(21) Appl. No.: 19/177,001

(22) Filed: Apr. 11, 2025

Related U.S. Application Data
(63) Continuation-in-part of application No. 18/788,321, filed on Jul. 30, 2024.

(51) Int. Cl. H10N 30/853; H04R 17/02

(52) U.S. Cl. CPC H10N 30/853; H04R 17/02; H04R 2201/003

(57) ABSTRACT

Disclosed herein are a microelectromechanical system (MEMS) devices comprising a first electrode layer, an aluminum nitride based piezoelectric layer, and a second electrode layer. The aluminum nitride based piezoelectric layer comprises a piezoelectric material of formula AlₓSc_{y}Yb_{z}N, AlₓY_{y}Yb_{z}N, AlₓSc_{y}Y_{z}N, or their combination, wherein x+y+z=1. Also disclosed are acoustic components comprising the piezoelectric material.

### CROSS-REFERENCE TO RELATED APPLICATIONS

This application is a continuation-in-part of U.S. application Ser. No. 18/788,321 filed Jul. 30, 2024, the disclosure of which is hereby incorporated in its entirety by reference herein.

### TECHNICAL FIELD

The present disclosure relates to piezoelectric materials and devices comprising piezoelectric materials. More specifically, the disclosure relates to MEMS devices, including ultrasonic acoustic components.

### BACKGROUND

Microelectromechanical systems (MEMS) are ubiquitous in modem technology, especially in electronic devices and sensors. These systems couple mechanics and electricity on a microscale, enabling new paradigms of sensing and processing. One major MEMS market is an ultrasonic transducer.

### SUMMARY

The disclosure pertains to microelectromechanical system (MEMS) devices comprising a first electrode layer, an aluminum nitride based piezoelectric layer, and a second electrode layer. The aluminum nitride based piezoelectric layer comprises a piezoelectric material of formula AlₓSc_{y}Yb_{z}N, wherein x+y+z=1. Also disclosed herein are acoustic components comprising the piezoelectric material.

In one or more embodiment, a microelectromechanical systems (MEMS) device is disclosed. The device includes a first electrode and a second electrode spaced apart from the first electrode by an aluminum nitride piezoelectric layer having a first material of formula (II): AlₓY_{y}Yb_{z}N (II), where x+y+z=1 and x is any number between 0.3 and 0.9. The z may be greater than y. z may be equal to y. The material may include Al_{0.5}Y_{0.25}Yb_{0.25}N. The device may also include a second material of formula (I): AlₓSc_{y}Yb_{z}N (I), where x+y+z=1 and x is any number between 0.3 and 0.9. The device may also include a second material of formula (III): AlₓSc_{y}Y_{z}N (III), where x+y+z=1 and x is any number between 0.3 and 0.9. The first material may have a c/a value between 1.3 and 1.5. The device may be an ultrasonic transducer.

In another embodiment, an acoustic component is disclosed. The component may include a substrate layer; a first electrode layer adjacent the substrate layer; a second electrode layer spaced apart from the first electrode layer; and an aluminum nitride based piezoelectric portion disposed between the first and second electrode layers and comprising a first material having a composition of formula (II): AlₓY_{y}Yb_{z}N (II), where x+y+z=1 and x is any number between 0.3 and 0.9. z may be greater than y. z may be equal to y. x may be 0.3 to 0.55. The aluminum nitride based piezoelectric portion may include a layer having a first material of formula (II) with a gradient in ratio of Y:Yb, Al:Yb, or Al:Y. The aluminum nitride based piezoelectric portion may include a first layer having a first material of formula (II) with a first ratio of Y:Yb and a second layer, discrete from the first layer, having a second material of formula (II) with a second ratio of Y:Yb, the first and second ratios being different.

In yet another embodiment, a piezoelectric material deposit is disclosed. The material includes a plurality of layers including a first material having a composition of formula (II): AlₓY_{y}Yb_{z}N (II), where x+y+z=1 and x is any number between 0.3 and 0.9, at least one of the plurality of layers having a different x, y, or z values in comparison to at least another one of the plurality of layers.

At least one of the plurality of layers may further include a second material having a composition of formula (II): AlₓY_{y}Yb_{z}N (II), where x+y+z=1 and x is any number between 0.3 and 0.9. At least one of the plurality of layers may also include a second material having a composition of formula (III): AlₓSc_{y}Y_{z}N (III), where x+y+z=1 and x is any number between 0.3 and 0.9. z may be greater than y. z may be equal to y. The plurality of layers may have a gradient in a ratio of Y:Yb, Al:Yb, or Al:Y.

### Selected Definitions and Nomenclature

As used herein, the terms “alloy”, “alloyed”, “alloying” and “dopant”, “doped”, or “doping” can be used interchangeably to refer to the addition of elements within the piezoelectric materials, disclosed herein. The terms “alloy” or “dopant” are not intended to limit the specific atomic amount of an element that is added or incorporated into the piezoelectric materials disclosed herein.

As used herein, the term “c/a” or “c/a value” are used interchangeably and refer to a piezoelectric material's crystallographic axial distortion. As is commonly used by crystallographers, “c” represents the (conventionally third) crystallographic lattice vector length, which is approximately aligned with the polarization field, and “a” represents the crystallographic lattice vector's or vectors' length approximately transverse to the polarization field.

As used herein “wurtzite” phase crystal structure refers to a structure in which the anions have a hexagonal close packed arrangement with the cations occupying one type of tetrahedral hole.

The term “about” is used in conjunction with numeric values to include normal variations in measurements as expected by persons skilled in the art, and is understood to have the same meaning as “approximately” and to cover a typical margin of error, such as ±15%, ±10%, ±5%, ±1%, ±0.5%, or even ±0.1% of the stated value. The term “about” also encompasses amounts that differ due to different equilibrium conditions for a composition resulting from a particular initial composition. Whether or not modified by the term “about,” the claims include equivalents to the quantities.

It should be noted that, as used in this specification and the appended claims, the singular forms “a,” “an,” and “the” include plural referents unless the content clearly dictates otherwise. Thus, for example, reference to a composition containing “a compound” includes having two or more compounds that are either the same or different from each other. It should also be noted that the term “or” is generally employed in its sense including “and/or” unless the content clearly dictates otherwise. As used herein, “and/or” refers to and encompasses any and all possible combinations of one or more of the associated listed items, as well as the lack of combinations when interpreted in the alternative (“or”).

In the interest of brevity and conciseness, any ranges of values set forth in this specification contemplate all values within the range and are to be construed as support for claims reciting any sub-ranges having endpoints which are real number values within the specified range in question. By way of a hypothetical illustrative example, a disclosure in this specification of a range of from 1 to 5 shall be considered to support claims to any of the following ranges: 1-5; 1-4; 1-3; 1-2; 2-5; 2-4; 2-3; 3-5; 3-4; and 4-5.

The term “substantially” is utilized herein to represent the inherent degree of uncertainty that can be attributed to any quantitative comparison, value, measurement, or other representation. The term “substantially” is also utilized herein to represent the degree by which a quantitative representation can vary from a stated reference without resulting in a change in the basic function of the subject matter at issue.

The term “comprise,” “comprises,” and “comprising” as used herein, specify the presence of the stated features, integers, steps, operations, elements, and/or components, but do not preclude the presence or addition of one or more other features, integers, steps, operations, elements, components, and/or groups thereof.

As used herein, the transitional phrase “consisting essentially of” means that the scope of a claim is to be interpreted to encompass the specified materials or steps recited in the claim and those that do not materially affect the basic and novel characteristic(s) of the claimed invention. Thus, the term “consisting essentially of” when used in a claim of this invention is not intended to be interpreted to be equivalent to “comprising.”

As used herein, the terms “increase,” “increasing,” “increased,” “enhance,” “enhanced,” “enhancing,” and “enhancement” (and grammatical variations thereof) describe an elevation of at least about 1%, 5%, 10%, 15%, 25%, 50%, 75%, 100%, 150%, 200%, 300%, 400%, 500% or more as compared to a control.

As used herein, the terms “reduce,” “reduced,” “reducing,” “reduction,” “diminish,” and “decrease” (and grammatical variations thereof), describe, for example, a decrease of at least about 1%, 5%, 10%, 15%, 20%, 25%, 35%, 50%, 75%, 80%, 85%, 90%, 95%, 97%, 98%, 99%, or 100% as compared to a control. In particular embodiments, the reduction can result in no or essentially no (i.e., an insignificant amount, e.g., less than about 10% or even 5% or even 1%) detectable activity or amount.

The terms “preferred” and “preferably” refer to embodiments that may afford certain benefits, under certain circumstances. However, other embodiments may also be preferred, under the same or other circumstances. Furthermore, the recitation of one or more preferred embodiments does not imply that other embodiments are not useful and is not intended to exclude other embodiments from the scope of the present disclosure.

The terms “over,” “under,” “between,” and “on” as used herein refer to a relative position of one component or material with respect to other components or materials where such physical relationships are noteworthy. For example, in the context of materials, one material or material disposed over or under another may be directly in contact or may have one or more intervening materials. Moreover, one material disposed between two materials or materials may be directly in contact with the two layers or may have one or more intervening layers. In contrast, a first material or material “on” a second material or material is in direct contact with that second material/material. Similar distinctions are to be made in the context of component assemblies.

As used throughout this description, and in the claims, a list of items joined by the term “at least one of” or “one or more of” can mean any combination of the listed terms. For example, the phrase “at least one of X, Y or Z” can mean X; Y; Z; X and Y; X and Z; Y and Z; or X, Y and Z

“A”, “an”, and “the” as used herein refers to both singular and plural referents unless the context clearly dictates otherwise. By way of example, “a processor” programmed to perform various functions refers to one processor programmed to perform each and every function, or more than one processor collectively programmed to perform each of the various functions.

### BRIEF DESCRIPTION OF THE DRAWINGS

FIG. 1 depicts a cross-sectional view of an embodiment of a MEMS device comprising piezoelectric materials in accordance with embodiments disclosed herein.

FIG. 2 depicts a cross-sectional view of an ultrasound transducer in accordance with embodiments disclosed herein.

FIG. 3 depicts graphical results of e_{31,f} graphed versus permittivity ε_{zz}=ε_{r,33} for the simulated materials, as disclosed herein.

FIG. 4 is a schematic of a unit cell of a wurtzite Al—Yb—Sc—N alloy transducer in accordance with embodiments disclosed herein.

FIG. 5A shows a graphical depiction of formation energy plots for the wurtzite configuration of Al—Sc—Yb—N materials, disclosed herein.

FIG. 5B shows a graphical depiction of formation energy plots for the rocksalt configuration of Al—Sc—Yb—N materials, disclosed herein.

FIG. 5C shows a graphical depiction of formation energy plots for calculated c/a ratio for wurtzite configuration of Al—Sc—Yb—N materials, disclosed herein.

FIGS. 6A and 6B are plots of piezoelectric coefficient e_{31,f} for various doping levels of the herein-disclosed materials.

FIGS. 6C and 6D are plots of an overall efficiency of electromechanical coupling for various doping levels of the herein-disclosed materials.

FIGS. 6E and 6F are plots of the dielectric permittivity for various doping levels of the herein-disclosed materials.

FIGS. 6G and 6H are plots of SCAN bandgap for various doping levels of the herein-disclosed materials.

FIG. 6I is a plot of speed of sound for various doping levels of the herein-disclosed materials.

FIG. 6J is a plot of values of e_{31,f} vs. the permittivity for the herein-disclosed materials in the Al—Y—Yb—N space.

FIG. 7 shows a representative schematic of a unit cell of a wurtzite AlₓY_{y}Yb_{z}N alloy transducer in accordance with embodiments disclosed herein.

FIGS. 8A and 8B are plots of energy of formation E_{F} for rocksalt and wurtzite formations of AlYYbN materials, top and bottom, respectively.

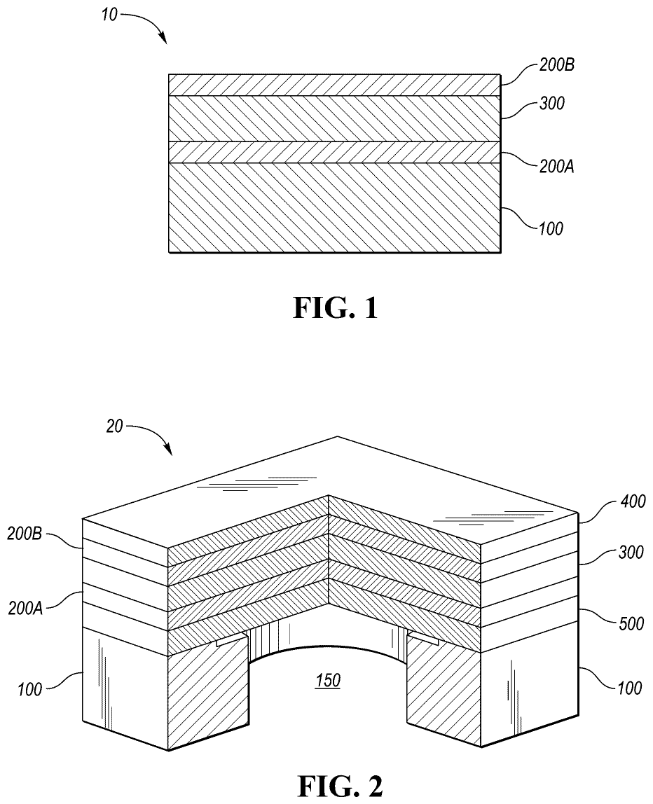

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative bases for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical application. Various combinations and modifications of the features consistent with the teachings of this disclosure, however, could be desired for particular applications or implementations.

Piezoelectricity is an electro-mechanical phenomenon observed in specific asymmetric crystal structures, such as found in quartz and various ceramics. The direct piezoelectric effect is manifested when a piezoelectric material undergoes physical stress, leading to polarization and the generation of a voltage across it. Conversely, the converse piezoelectric effect occurs when the material is subjected to an electrical field, resulting in deformation—either expansion or contraction—depending on the direction of the field. Upon exposure to an electric AC signal, the piezoelectric material undergoes vibrational motion, alternately contracting and expanding. This phenomenon gives rise to the emission of ultrasound waves, illustrating the practical application of piezoelectricity in the conversion of mechanical energy into electrical energy and vice versa.

Piezoelectric materials are widely employed in ultrasonic transducers owing to their exceptional electro-mechanical properties. These materials exhibit a high-frequency response, allowing for the efficient generation and detection of ultrasonic waves crucial in applications like medical imaging, cleaning processes, and distance measurement. Their compact and lightweight nature makes them suitable for diverse applications with space constraints and portability requirements. Additionally, piezoelectric transducers offer a broad frequency range, enabling adaptation to various operational needs in fields such as medical diagnostics, industrial inspections, automotive sensors, and underwater communication. Renowned for their durability and stability, these materials ensure reliable performance over time. The precision and sensitivity of piezoelectric transducers make them ideal for tasks demanding accurate detection of fine details or subtle changes, as seen for example in medical imaging. Moreover, their low electrical power consumption contributes to energy efficiency in devices utilizing ultrasonic technology. Overall, the unique combination of properties in piezoelectric materials positions them as indispensable components in ultrasonic transducer applications.

Suppose we have a material with a piezoelectric tensor e and a compliance tensor s^{E} under constant electric field (inverse of a stiffness tensor c^{E} under constant electric field). In MEMS devices, typically a thin piezoelectric film is clamped to a substrate, e.g. Si substrate. For such a thin film clamped on a substrate, the key coefficients are e_{31,f} and d_{33,f}, given as follows:

$$\text{?} = \frac{{d}_{31}}{\text{?} + \text{?}} = {e}_{31} - \frac{\text{?}}{\text{?}} {e}_{33} \vert \text{?} \vert > \vert {e}_{31} \vert$$

$$\text{?} = \frac{{e}_{33}}{\text{?}} = {d}_{33} - \frac{\text{?}}{\text{?} + \text{?}} {d}_{31} < {d}_{33}$$

$$\text{?} \text{indicates text missing or illegible when filed}$$

The selection of piezoelectric materials is dependent on their applications, with each application having a figure of merit (FoM) composed of different physical properties (especially the piezoelectric coefficient and permittivity) of the piezoelectric material. The material with the highest FoM is typically the best material for the selected application.

For sensor applications (e.g. microphones), the sensitivity is described by the piezoelectric coefficient e_{31,f} and the permittivity ε_{r,33}, with the FoM being e_{31,f}/ε_{r,33} (with high e_{31,f} being advantageous for generation of high charge at given stress and a low ε_{r,33} being advantageous for yielding higher voltages with given charge), and thus AlN is preferred over lead zirconate titanate (PZT). PZT exhibits a superior piezoelectric constant e_{31, f} (piezoelectric constants vary with respect to doping ratio), which has advantages for actuator applications. The FoM for actuators is denoted as e_{31, f} and PZT is one of the most studied and commercially used material for applications in actuators like micro-mirrors. However, a drawback of PZT is its lead content which makes it target of RoHS and REACH regulations and limits its compatibility with semiconductor fab processes. Therefore, although PZT is an established piezoelectric material for application in MEMS, a lead-free replacement material is crucial even for actuation. The key FoM for ultrasound is typically e_{31,f}²/εᵣ as for ultrasound applications an ultrasound wave has to be exited (actuation, e_{31,f}) and an incoming ultrasound wave has to be detected (sensing, e_{31,f}/ε_{r,33}).

One way of improving the performance of the piezoelectric materials is doping the AlN with Sc, e.g. using Al_{0.6}Sc_{0.4}N. Currently, the highest FoM for ultrasound devices can be achieved by combining AlN (or AlScN) for detection and PZT for actuation. However, this combination is very expensive as two piezoelectric processes have to be combined in one device.

Hence, for ultrasound devices, current piezoelectric materials with high FoM require a combination of materials which require expensive and complex deposition processes. Thus, there remains a need for AlN based piezoelectric materials which have a high FoM and can be manufactured or deposited through more efficient and economical processes.

In one or more embodiments, an aluminum nitride (AlN) based piezoelectric material is disclosed. Also disclosed are MEMS devices incorporating the herein-disclosed piezoelectric material(s). The piezoelectric materials disclosed herein are optimized for incorporation in ultrasound devices. The piezoelectric materials include quaternary piezoelectric alloys, which have higher figure of merit (FoM), e_{31,f}²/ε_{r,33}, for ultrasound applications, when compared to currently used piezoelectric materials.

In one embodiment, a microelectromechanical system (MEMS) device 10 is disclosed. A MEMS is a micro-electro-mechanical system including mechanical and electrical circuits fabricated using microscale semiconductor manufacturing. The MEMS device may include an ultrasonic transducer configured to transmit ultrasound waves and receive echoes from objects, tissues, materials, or their combination. The MEMS may include a piezoelectric micromachines ultrasounds transducer (PMUT) configured to generate ultrasounds by mechanical vibration when voltage is applied.

The MEMS device may include a substrate 100, an aluminum nitride based piezoelectric layer 300, a first electrode layer 200A and a second electrode layer 200B. The aluminum nitride piezoelectric material in in the Al-based piezoelectric layer 300 may include of one or more materials of one or more formulas disclosed herein, including a material of formula (I), (II), (III), or their combination.

In one or more embodiments, the MEMS device 10 aluminum nitride based piezoelectric material or layer may include a material of formula (I):

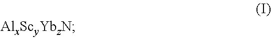

a material having a formula (II):

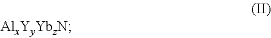

a material having a formula (III):

AlₓSc_{y}Y_{z}N (III), or their combination.

In formulas (I), (II), (III), x+y+z=1. In the materials of formulas (I), (II), (III), x, y, z may be the same or different.

In formulas (I), (II), (III), x may be 0.3<x≤0.9. x may be 0.5<x≤0.7. x may be x=0.4 to 0.6. x may be 0.3, 0.35, 0.4, 0.45, 0.5, 0.55, 0.6, 0.65, 0.7, 0.75, 0.8, 0.85, or 0.9. x may be within a range using any of the numerals disclosed herein. x may be below 0.6. x may be equal to or lower than 0.55.

In formulas (I), (II), (III), the relationship between y and z may be defined as |y−z| <0.2 or |y−z|<0.1. In formulas (I), (II), (III), z may be greater than y (z>y), lesser than y (z<y), or equal to y (z=y). z may have a greater value than y such that z>y.

In formulas (I), (II), (III), y may be 0, 0.05, 0.075, 0.1, 0.125, 0.15, 0.175, 0.2, 0.225, 0.25, 0.275, 0.3, 0.325, 0.35, 0.375, 0.4, 0.425, 0.45, 0.5, or 0.55. y may be 0.2 to 0.3. y may be 0.1 to 0.3. y may be within a range using any of the numerals disclosed herein.

In formulas (I), (II), (III), z may be 0, 0.05, 0.075, 0.1, 0.125, 0.15, 0.175, 0.2, 0.225, 0.25, 0.275, 0.3, 0.325, 0.35, 0.375, 0.4, 0.425, 0.5, or 0.55. z may be 0.2-0.3. z may be 0.1 to 0.3. z may be within a range using any of the numerals disclosed herein.

Non-limiting example ratios of Y:Yb, Yb:Sc, Sc:Y in the formulas (I), (II), (III) may be 1:1, 1:2, 2:1, 2:3, 3:2, 1:3, 3:1, 1:4, 4:1, 1:5, 5:1, 2:5, 5:2, 3:4, 4:3, 3:5, 5:3, etc.

In non-limiting examples, the material may have formula (I) and the following conditions may apply: x+y+z=1, 0.3<x<0.9, and |y−z|<0.2 or x+y+z=1, 0.5<x<0.7, |y−z|<0.1, and z>y, or x=0.4-0.6, y=0.2-0.3, z=0.2-0.3, or x+y+z=1, x is 0.3 to 0.55.

In formulas (I), (II), (III), an amount of Al may be substituted with Ga or In. The substitution may be up to about 1, 2, 3, 4, 5, 6, 7, 8, 9, 10, 15, 20, 25, 30, 35, 40, 45, or 50 atomic %, based on the total percent of Al in the material. Because Ga and In are heavier and less piezoelectrically active than Al, the preferable value is about 10 atomic % or less.

The doped material may include one or more compounds disclosed herein. One or more compounds disclosed herein may be explicitly excluded from the material, layer, component. In a non-limiting example, the material may include one or more of the following compounds: Al_{0.4}Sc_{0.2}Yb_{0.4}N, Al_{0.35}Sc_{0.1}Yb_{0.55}N, A_{10.45}Sc_{0.15}Yb_{0.4}N, Al_{0.5}Sc_{0.2}Yb_{0.3}N, Al_{0.38}Sc_{0.12}Yb_{0.5}N, Al_{0.3}Sc_{0.2}Yb_{0.5}N, Al_{0.35}Sc_{0.25}Yb_{0.4}N, Al_{0.4}Sc_{0.2}Yb_{0.4}N, Al_{0.45}Sc_{0.3}Yb_{0.25}N, Al_{0.48}Sc_{0.22}Yb_{0.3}N, Al_{0.5}Sc_{0.2}Yb_{0.3}N, Al_{0.35}Sc_{0.45}Yb_{0.2}N, Al_{0.4}Sc_{0.35}Yb_{0.25}N, Al_{0.45}Sc_{0.35}Yb_{0.2}N, Al_{0.48}Sc_{0.3}Yb_{0.22}N, Al_{0.5}Sc_{0.2}Yb_{0.3}N, Al_{0.42}Sc_{0.3}Yb_{0.28}N, Al_{0.6}Sc_{0.05}Yb_{0.35}N, Al_{0.7}Sc_{0.1}Yb_{0.2}N, Al_{0.8}Sc_{0.05}Yb_{0.15}N, Al_{0.85}Sc_{0.03}Yb_{0.12}N, Al_{0.9}Sc_{0.02}Yb_{0.08}N, Al_{0.3}Sc_{0.35}Yb_{0.35}N, Al_{0.4}Sc_{0.3}Yb_{0.3}N, Al_{0.5}Sc_{0.25}Yb_{0.25}N, Al_{0.6}Sc_{0.2}Yb_{0.2}N, Al_{0.7}Sc_{0.15}Yb_{0.15}N, Al_{0.8}Sc_{0.1}Yb_{0.1}N, Al_{0.9}Sc_{0.05}Yb_{0.05}N.

In a non-limiting example, the material may include one or more of the following compounds: Al_{0.4}Y_{0.2}Yb_{0.4}N, Al_{0.35}Y_{0.1}Yb_{0.55}N, Al_{0.45}Y_{0.15}Yb_{0.4}N, Al_{0.5}Y_{0.2}Yb_{0.3}N, Al_{0.38}Y_{0.12}Yb_{0.5}N, Al_{0.3}Y_{0.2}Yb_{0.5}N, Al_{0.35}Y_{0.25}Yb_{0.4}N, Al_{0.4}Y_{0.2}Yb_{0.4}N, Al_{0.45}Y_{0.3}Yb_{0.25}N, Al_{0.48}Y_{0.22}Yb_{0.3}N, Al_{0.5}Y_{0.2}Yb_{0.3}N, Al_{0.35}Y_{0.45}Yb_{0.2}N, Al_{0.4}Y_{0.35}Yb_{0.25}N, Al_{0.45}Y_{0.35}Yb_{0.2}N, Al_{0.48}Y_{0.3}Yb_{0.22}N, Al_{0.5}Y_{0.2}Yb_{0.3}N, Al_{0.42}Y_{0.3}Yb_{0.28}N, Al_{0.6}Y_{0.05}Yb_{0.35}N, Al_{0.7}Y_{0.1}Yb_{0.2}N, Al_{0.8}Y_{0.05}Yb_{0.15}N, Al_{0.85}Y_{0.03}Yb_{0.12}N, Al_{0.9}Y_{0.02}Yb_{0.08}N, Al_{0.3}Y_{0.35}Yb_{0.35}N, Al_{0.4}Y_{0.3}Yb_{0.3}N, Al_{0.5}Y_{0.25}Yb_{0.25}N, Al_{0.6}Y_{0.2}Yb_{0.2}N, Al_{0.7}Y_{0.15}Yb_{0.15}N, Al_{0.8}Y_{0.1}Yb_{0.1}N, Al_{0.9}Y_{0.05}Yb_{0.05}N.

In a non-limiting example, the material may include one or more of the following compounds: Al_{0.4}Sc_{0.2}Y_{0.4}N, Al_{0.35}Sc_{0.1}Y_{0.55}N, Al_{0.45}Sc_{0.15}Y_{0.4}N, Al_{0.5}Sc_{0.2}Y_{0.3}N, Al_{0.38}Sc_{0.12}Y_{0.5}N, Al_{0.3}Sc_{0.2}Y_{0.5}N, Al_{0.35}Sc_{0.25}Y_{0.4}N, Al_{0.4}Sc_{0.2}Y_{0.4}N, Al_{0.45}Sc_{0.3}Y_{0.25}N, Al_{0.48}Sc_{0.22}Y_{0.3}N, Al_{0.5}Sc_{0.2}Y_{0.3}N, Al_{0.35}Sc_{0.45}Y_{0.2}N, Al_{0.4}Sc_{0.35}Y_{0.25}N, Al_{0.45}Sc_{0.35}Y_{0.2}N, Al_{0.48}Sc_{0.3}Y_{0.22}N, Al_{0.5}Sc_{0.2}Y_{0.3}N, Al_{0.42}Sc_{0.3}Y_{0.28}N, Al_{0.6}SC_{0.05}Y_{0.35}N, Al_{0.7}Sc_{0.1}Y_{0.2}N, Al_{0.8}Sc_{0.05}Y_{0.15}N, Al_{0.85}Sc_{0.03}Y_{0.12}N, Al_{0.9}Sc_{0.02}Y_{0.08}N, Al_{0.3}Sc_{0.35}Y_{0.35}N, Al_{0.4}Sc_{0.3}Y_{0.3}N, Al_{0.5}Sc_{0.25}Y_{0.25}N, Al_{0.6}Sc_{0.2}Y_{0.2}N, Al_{0.7}Sc_{0.15}Y_{0.15}N, Al_{0.8}Sc_{0.1}Y_{0.1}N, Al_{0.9}Sc_{0.05}Y_{0.05}N.

In one embodiment, the MEMS device 10, incorporates a piezoelectric layer 300 which contains a plurality of alternating layers. The layers have a Sc-rich composition and Yb-rich composition or Y-rich composition, in an alternating configuration. The layers may be discrete layers. Such alternation is found to correlate with a high piezoelectric coefficient e_{31,f}. Each alternating layer in the plurality of alternating layers can have a thickness of about 0.3 to 30, 0.4 or 25, or 0.5 to 20 nm.

The piezoelectric material may have a c/a value between 1.2 and 1.5 including 1.25, 1.3, 1.35, 1.4, 1.45, or 1.5. The c/a ratio in piezoelectric materials refers to the crystal lattice dimensions and plays a role in piezoelectric performance. Piezoelectricity arises from competition between wurtzite and hexagonal phases in the crystal lattice. The c/a ratio is a measure of the distortion from the hexagonal to the wurtzite phase. A higher c/a ratio (greater than 1.2) indicates a more tetragonal distortion which indicates a higher-energy hexagonal phase and a weaker piezoelectric effect.

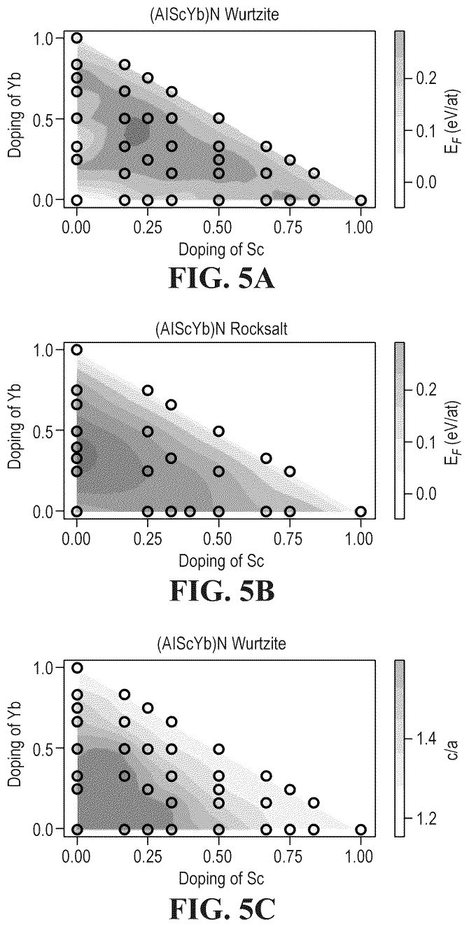

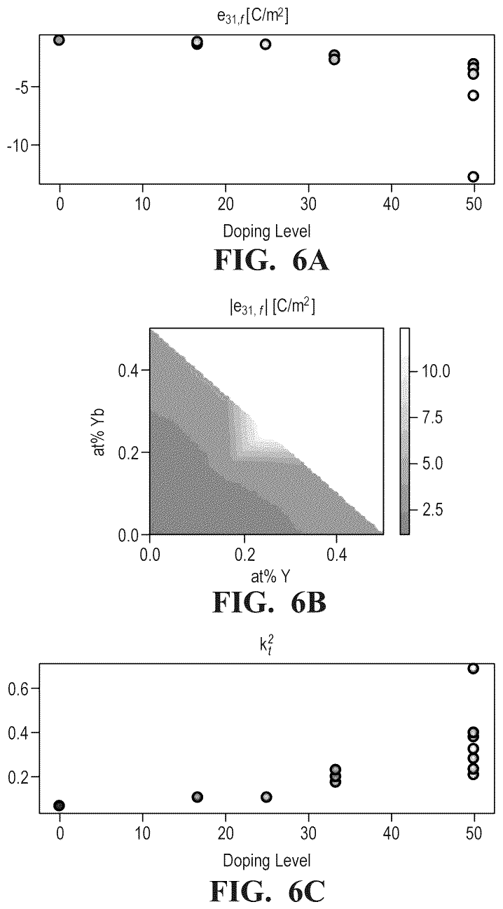

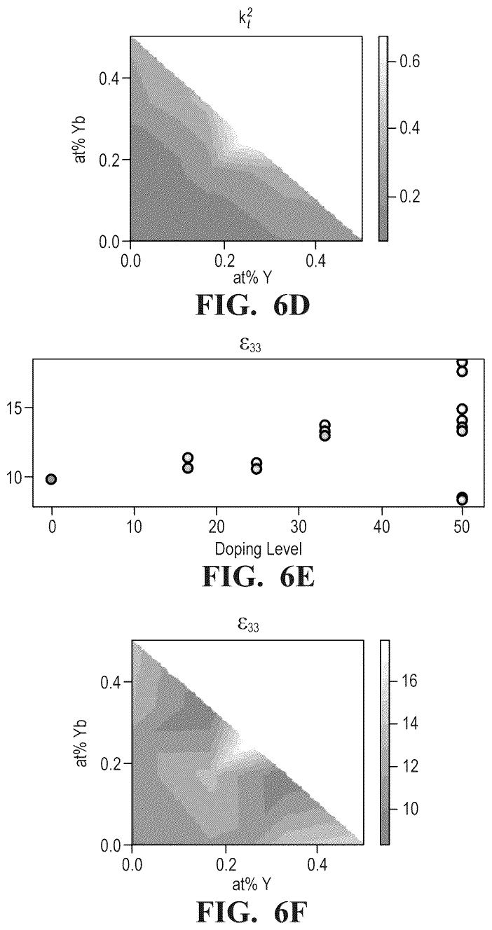

FIGS. 5A and 5B show the computed energy of formation of a given composition AlScYbN in the wurtzite and the rocksalt phase, respectively. The rocksalt phase is not piezoelectric, whereas the wurtzite phase is piezoelectric. It is known that if the alloying of AlN with Sc is more than 30-50%, there is a significant risk of rocksalt formation, which is undesirable for piezoelectric applications. This risk of rocksalt formation exists because the energy of the wurtzite and the rocksalt are close to each other, so it is difficult to preferentially grow the desired wurtzite phase. This is seen in FIGS. 5A and 5B. However, the addition of a moderate amount of Yb accomplishes two things: it stabilizes the wurtzite phase, by making the rocksalt higher energy (the darker shade on the left of FIG. 5B), and it also raises the piezoelectric e_{31,f} (shown on FIG. 3). FIG. 5C shows the computed value of c/a or the tetragonal distortion as a function of Yb and Sc doping. A lower value of c/a is correlated to a higher piezoelectric effect. In FIG. 5C, both Yb and Sc are good piezoelectric additives because of their ionic and polar character.

The piezoelectric layer 300 has a thickness of about 50-2000 nm, or 100-2000 nm, or 200-2000 nm, or 300-2000 nm, or 400-2000 nm, or 500-2000 nm, or 600-2000 nm, or 700-2000 nm, or 800-2000 nm, or 900-2000 nm, or 50-1000 nm, or 100-1000 nm, or 200-1000 nm, or 300-1000 nm, or 400-1000 nm, or 500-1000 nm, or 600-1000 nm, or 700-1000 nm, or 800-1000 nm, or 900-1000 nm. In certain embodiments, the piezoelectric layer 300 has a thickness of about 50-500 nm, or 100-400 nm, or 200-300 nm, or any value or range therebetween.

The substrate layer 100 may include a ceramic material such as alumina, sapphire, glass, single-crystalline or polycrystalline aluminum nitride, gallium nitride, silicon carbide or a silicon, Si (100) or Si (111) substrate. Silicon wafers are the most common substrate for MEMS devices due to their scalability towards mass manufacturing and compatibility with various manufacturing process steps. The substrate may be a flexible substrate such as polyimide.

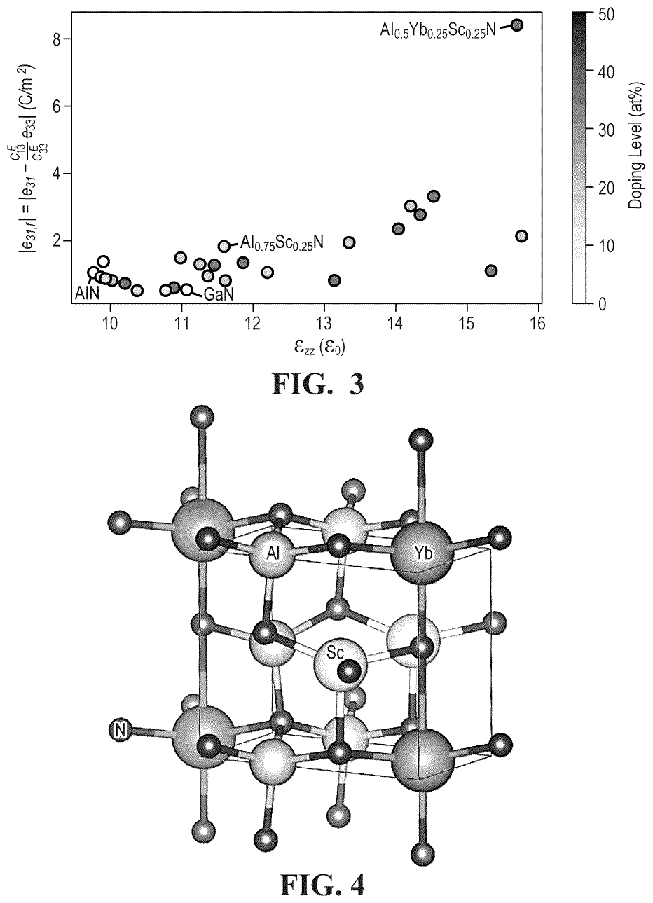

In certain embodiments, portions of the substrate layer 100 can be removed such as the device shown in FIG. 2. This removal step and geometry will depend on the type of piezoelectric device being fabricated.

In one embodiment, an acoustic component MEMS device 20, is disclosed as shown in FIG. 2 (e.g. an acoustic sensor). The device 20 incorporates a substrate material 100, and an optional structural layer 500 deposited thereon. The substrate material 100 has an internal diaphragm 150. The device 20 further incorporates a first electrode 200A and a second electrode 200B, with an AlN based piezoelectric layer 300 sandwiched or disposed between the two electrode layers. Above the second electrode layer is a passivation layer 400. The passivation layer 400, in one embodiment, is an oxide layer, such as SiO₂ or SiN. The passivation layer is optional, in certain embodiments.

The first and second electrode 200A and 200B can be composed of materials that are commonly used for electrode layers in MEMS devices, including Pt, Au, Cu, Al, W, Mo, TiN, Ti, doped Si, and combinations thereof. The thickness of the electrode layers will vary per application of the MEMS device, but can be in the range of about 0.05 to 0.5, 0.07 to 0.4, or 0.1 to 0.3 μm.

The substrate layer 100 may include a material such as Si (100) with a thickness of about 200 μm to 1.5 mm, or 380 μm to 725 μm, or 675 μm or 725 μm and a diameter in the area of 100 mm-300 mm, or 150 mm-200 mm, or 300 mm, or 100 mm. An electrically insulating passivation layer 400 may be grown on top of the substrate. A bottom electrode layer including M, W, Al, or doped Si, may be deposited next. Alternatively, the structural layer 500 may be deposited, for example, composed of SiO₂ or SiN, having a thickness of about 0.3-3.0 microns.

Additionally, a seed layer (not shown) may also be deposited onto an electrode such as the first electrode 200A. The seed layer is also sometimes referred to as a nucleation layer or a buffer layer. In one embodiment, the deposition of seed layer is an optional step. The purpose of this layer is to provide improved crystal growth and enhance crystal orientation for deposition of the functional piezoelectric material layer 300. The seed layer may enhance crystal orientation, e.g. by strain or lattice mismatch engineering, e.g. relaxing or increasing strains or lowering lattice mismatch to the main functional layer. The seed layer may be provided on top or below the bottom electrode layer.

It is to be understood that the seed layer deposition, while referenced as a single step for purposes of simplicity and brevity, can include multiple seed layers deposited in succession. In one embodiment, the seed layer may include AlN and may be deposited at a film thickness of about 10-50, 15-45, or 20-40 nm. The seed layer is deposited on the substrate via molecular beam epitaxy, chemical vapor deposition (CVD), pulsed laser deposition, reactive sputtering, or other appropriate methods that are known to those skilled in the art. In one example, an AlN seed layer can be deposited on a Si substrate, using an Al target in a sputtering chamber, at a temperature of 350° C. Base pressure of the sputtering chamber during deposition can be about 2×10⁻³ mbar. Gas flow introduced during sputtering can include, for example, 10 sccm of Ar and 40 sccm of N₂.

In at least one embodiment, the seed layer may include a material gradient in composition of a layer or multiple seed layers, e.g. starting at a higher x (Al-rich) near the first electrode and then decreasing the Al amount in a layer until the final composition (with high piezoelectric coefficient) is reached (e.g. within a thickness of about 50 nm). Then the layer with final composition may be deposited as the top deposition. As a result, the piezoelectric layer 300 may include a number of layers, each layer increasing a number of doped elements and decreasing number of Al in the direction from the first electrode to the second electrode. The highest amount of the doped elements being in the top layer adjacent the second electrode. The lowest amount of the doped elements being in the layer adjacent the first electrode.

In a non-limiting example, the material in the first deposition, adjacent the first electrode, may have x of about 0.5-0.9, gradually decreasing x to about 0.3 with the following depositions towards the depositions adjacent the second electrode. In another non-limiting example, the material may have a first layer having a first material with a first ratio of Y:Yb and a second layer having a second material with a second ratio of Y:Yb, the first and second ratios being different. The layers may be discrete layers. The material may have formula (I), (II), or (III).

In one or more embodiments, the piezoelectric layer 300, having a thickness of 50-2000, 100-1500 nm, or 200-1000 nm, may be deposited through deposition techniques including chemical vapor deposition (MOCVD), molecular beam epitaxy (MBE), or sputter deposition. The piezoelectric layer 300, of device 20 shown in FIG. 2 includes an aluminum nitride piezoelectric material such as a material of formula (I), (II), (III), or their combination. In a non-limiting example, the material may include a material of formula (I): AlₓSc_{y}Yb_{z}N, wherein x+y+z=1, 0.3<x≤0.9, and |y−z|<0.2. In further embodiments, the aluminum nitride piezoelectric material is AlₓSc_{y}Yb_{z}N, wherein x+y+z=1, 0.5<x<0.7, |y−z|<0.1, and z>y. In another non-limiting example, the aluminum nitride piezoelectric material is AlₓSc_{y}Yb_{z}N, wherein x=0.4-0.6, y=0.2-0.3, z=0.2-0.3. In another embodiment, the material of formula (I) has the following conditions: x+y+z=1, x<0.5 or x+y+z=1, z>y. In another example, the aluminum nitride piezoelectric material may include a material of formula (II). In another example, the aluminum nitride piezoelectric material may include a material of formula (III). In another example, the aluminum nitride piezoelectric material may include a material of formula (II) and a material of formula (I).

The material may be deposited in discrete layers. The layers may have the same or different composition. The layers may alternate in a regular pattern or be irregular. For example, a number of first layers may include a material of formula (I), a number of second layers may include a material of formula (II) which is Y-rich (y>z), a number of third layers may include a material of formula (II) which is Yb-rich (z>y), etc. The number of layers may be about 1, 2, 3, 4, 5, 6, 7, 8, 9, 10, or more.

In a non-limiting example, the doped piezoelectric material may include one or more layers of a material where y=z and one or more layers where z>y such as one or more layers having Al_{0.5}Y_{0.25}Yb_{0.25}N and one or more layers having Al_{0.4}Sc_{0.2}Yb_{0.4}N. In another non-limiting example, the material may include one or more layers of Al_{0.55}Y_{0.1}Yb_{0.35}N and one or more layers of Al_{0.5}Sc_{0.25}Y_{0.25}N. In another non-limiting example, the material may include one or more layers of Al_{0.55}Sc_{0.1}Yb_{0.35}N and one or more layers of Al_{0.5}Sc_{0.25}Y_{0.25}N.

The doped piezoelectric material disclosed herein may be deposited by sputter deposition, molecular beam epitaxy (MBE), or chemical vapor deposition techniques such as metalorganic chemical vapor deposition (MOCVD), low pressure chemical vapor deposition (LPCVD), or atomic layer deposition (ALD).

In a non-limiting example, the deposition method is sputtering, including multi-target/source sputtering or single-target sputtering. A multi-target sputter deposition may be utilized, where multiple separate targets are used, such as AlSc and YbN targets, or AlSc and AlYb targets, or AlSc and YN targets, or AlSc and AlY targets, or AlY and YbN targets, or AlY and YYb targets, in the sputtering system. Alternatively, all materials may be combined into a single AlₓY_{y}Yb_{z}, AlₓSc_{y}Yb_{z}, or AlₓSc_{y}Yb_{z} target with nitrogen collected from the sputtering gas. A target made of AlₓY_{y}Yb_{z}N, AlₓSc_{y}Yb_{z}, or AlₓSc_{y}Yb_{z} may be used.

The frequencies and pattern of the pulses may be used to achieve the desired crystal quality and composition (e.g., by using a higher sputtering power on one target as compared to the other). The target's composition may not be identical to the final composition, due to the different mobility and sputtering yields of each element within the sputtering chamber, which yield loss or accumulation of atoms in the thin films as compared to the target. These effects can be adjusted by increasing or lowering the corresponding atoms in the target. The piezoelectric film growth may be monitored for a specific desired composition, using in-situ techniques or post-deposition analysis to ensure the desired target composition and properties. Similarly, deposition parameters (power, pressure, N₂ or Ar partial pressures, wafer temperature, DC-bias, distance target to wafer, etc.) are adjusted as needed to achieve the desired film characteristics.

The chamber may be evacuated to create a high vacuum environment. Nitrogen or argon gas may be introduced into the chamber to serve as the sputtering gas. Rf or dc power may be applied to targets to initiate the sputtering. The power supplied to each target to control the deposition rates of the respective materials may be dynamically controlled. The power can be oscillatory, pulsed, or be incorporated into a feedback loop with in-situ monitoring. The film growth may be monitored using in-situ techniques or post-deposition analysis to ensure the desired composition and properties. The deposition parameters (power, pressure, N₂ or Ar partial pressures, wafer temperature, AC or DC-bias, pulsed sputtering, distance target to wafer, etc.) may be adjusted as needed to achieve the desired film characteristics.

Once the piezoelectric layer 300 is deposited, the second electrode layer 200B can then be deposited thereon, e.g. Al, Mo, W, or poly-Si, also by sputtering or other deposition techniques currently known and utilized in the art. An optional annealing step may further be conducted to improve crystal quality, optionally with an applied AC or DC electric field. A stack may be formed. The optional annealing step can also be applied before the second electrode layer 200B is deposited.

The piezoelectric properties of the proposed AlN alloys disclosed herein were computed with first principles calculations. The structural parameters were computed by density functional theory (DFT) as implemented in the Vienna ab-initio Simulation Package (VASP), using the standard set of Perdew-Burke-Ernzerhof (PBE) functional and plane augmented wave (PAW) pseudopotentials. In a case of multiple possible structures for a given composition, low-energy structures were selected with the assistance of an alloy cluster expansion. In the event multiple structures have similar energies of formation at a given composition, they were each plotted on the graph.

The piezoelectric properties were computed with the density functional perturbation theory (DFPT) natively implemented in VASP. Table 1A and 1B below provide various piezoelectric parameter values for the piezoelectric materials disclosed herein.

TABLE 1A

| | | # atoms | | | | |
|---|---|---|---|---|---|---|
| Label | Formula | in cell | C₁₁ (GPa) | C₃₃ | C₁₃ | C₄₄ |
| 0 | AlN | 4 | 377.246 | 357.35 | 98.558 | 112.484 |
| 6 | Al_{0.75}Sc_{0.25}N | 8 | 297.859 | 252.842 | 121.051 | 91.572 |
| 7 | Al_{0.75}Yb_{0.25}N | 8 | 264.956 | 253.359 | 120.677 | 80.725 |
| 9 | Al_{0.5}Sc_{0.25}Yb_{0.25}N | 8 | 246.001 | 146.073 | 128.693 | 91.218 |
| 20 | Al0.5Yb0.5N | 8 | 198.145 | 173.131 | 133.441 | 86.557 |
| 63 | Al0.83Sc0.17N | 12 | 318.652 | 281.406 | 114.853 | 99.15 |
| 208 | Al0.67Sc0.17Yb0.17N | 12 | 294.276 | 200.578 | 104.618 | 87.599 |
| 213 | Al0.67Sc0.17Yb0.17N | 12 | 295.924 | 183.716 | 106.364 | 87.721 |
| 497 | Al0.67Sc0.33N | 12 | 297.343 | 213.718 | 120.005 | 94.327 |
| 499 | Al0.67Yb0.33N | 12 | 276.639 | 243.119 | 111.642 | 85.978 |

TABLE 1B

| Label | Formula | εₓₓ (ε₀) | ε_{yy} | ε_{zz} | e₃₁ (C/m²) | e₃₃ | e_{31, f} |
|---|---|---|---|---|---|---|---|
| 0 | AlN | 8.217 | 8.217 | 9.743 | −0.584 | 1.464 | −1.062 |
| 6 | Al_{0.75}Sc_{0.25}N | 9.773 | 9.818 | 11.584 | −0.672 | 1.881 | −1.821 |
| 7 | Al0.75Yb0.25N | 9.951 | 9.984 | 10.533 | −0.555 | 1.619 | −1.491 |
| 9 | Al0.5Sc0.25Yb0.25N | 10.943 | 10.994 | 15.725 | −0.962 | 3.348 | −8.721 |
| 20 | Al0.5Yb0.5N | 10.194 | 10.915 | 13.553 | −0.811 | 2.413 | −3.71 |
| 63 | Al0.83Sc0.17N | 9.235 | 9.281 | 11.191 | −0.672 | 1.817 | −1.604 |
| 208 | Al0.67Sc0.17Yb0.17N | 10.072 | 9.728 | 13.356 | −0.509 | 2.117 | −1.989 |
| 213 | Al0.67Sc0.17Yb0.17N | 9.946 | 9.797 | 13.579 | −0.49 | 2.299 | −2.395 |
| 497 | Al0.67Sc0.33N | 10.285 | 10.077 | 14.973 | −0.881 | 2.662 | −3.168 |
| 499 | Al0.67Yb0.33N | 10.162 | 9.928 | 15.083 | −0.923 | 2.349 | −2.411 |

Further, the piezoelectric tensor and electromechanical coupling constant were computed with first principles calculations. The calculations shown here used DFT as implemented in VASP with a PBE functional and PAW pseudopotentials. The piezoelectric properties were computed with the DFPT implementation of VASP. This method provided the key tensors of interest: e (piezoelectric coupling between stress and electric field), c^{D} (stiffness under constant displacement field; corrected to under constant electric field via Ĉ^{D}=Ĉ^{E}+ê^{T}ϵ⁻¹ê), and ε (dielectric tensor, which is the coupling between displacement field and polarization).

For an ultrasound device, the key FoM is e_{3l,f}²/ε_{r,33}. It is not obvious which materials have the highest FoM. Many ternary and quaternary materials were thus screened, and promising materials were identified. The method was as follows:

The formation energy and bandgaps of ternary and quaternary materials was computed using DFT with the SCAN functional, including a lattice and site relaxation. The occupations of each site were iteratively refined using a cluster expansion that is fit to the DFT energies of the previous step. The lowest-energy configurations at each composition were selected. The PBE functional was used to re-relax for compatibility with DFPT. The stiffness, piezoelectric, and dielectric tensors were computed using DFPT with the PBE functional. The piezoelectric coefficient e_{31,f} with the formulas and then the FoM for ultrasound e_{31,f}²/ε_{r,33} was calculated.

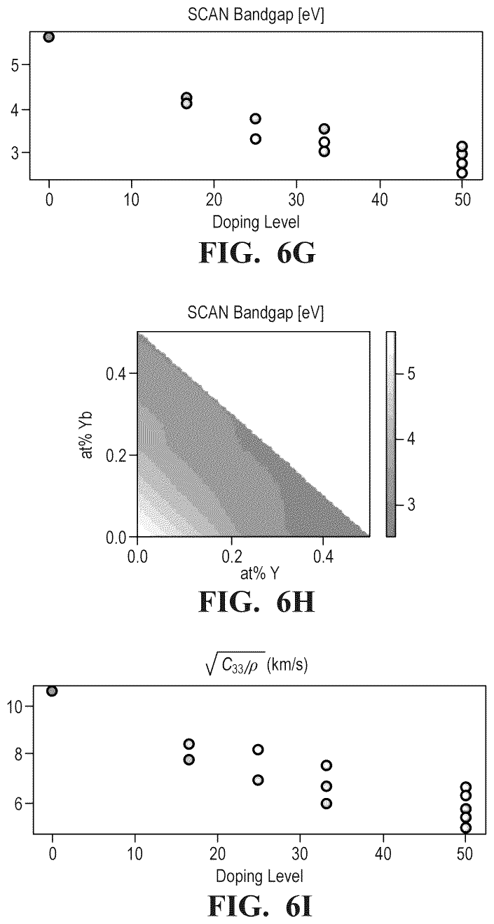

FIGS. 6A-6F show the computed KPI for materials in the Al—Y—Yb—N space, with chemical formula Al_{1-x-y}YₓYb_{y}N. This exercise helped to identify materials which fulfil not one, but several different properties, rendering the materials very suitable candidates for the MEMS application.

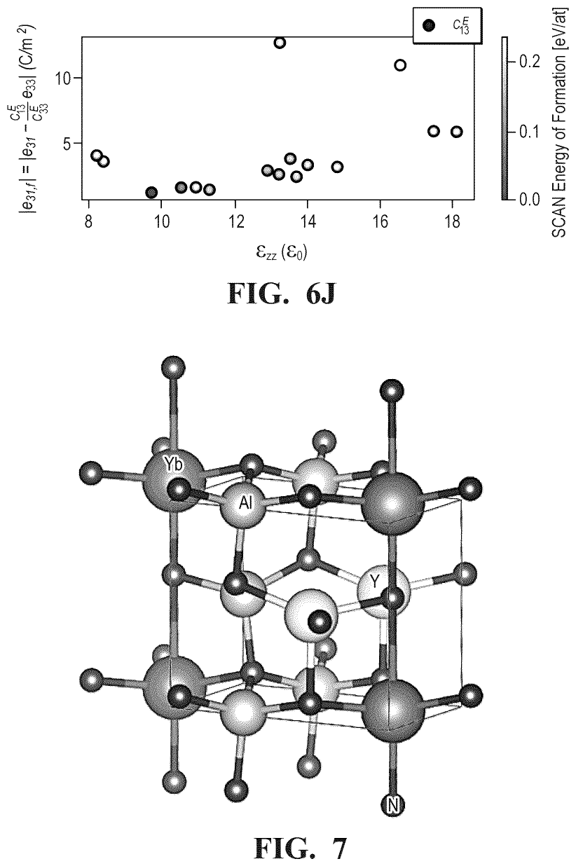

In the FIGS. 6A-7D, the “doping level” is x+y. There is one structure with a value of e_{31,f} greater than 10, and otherwise there are many materials between 4-5 which is significantly higher than AlN which is about 1. FIG. 6A shows the piezoelectric coefficient e_{31,f} for various doping levels. FIG. 6B also shows the piezoelectric coefficient e_{31,f} on the y axis. FIGS. 6A and 6B indicate how much a MEMS transducer deforms in response to an electric field (or changes voltage in response to a mechanical field). It was discovered that the best value is with multi-element doping instead of a single dopant.

FIG. 6C shows the efficiency of electrical to mechanical energy transfer or electromechanical coupling coefficient. As can be seen, the coupling coefficient reached 60% (axis y), providing a very good result compared to state of the art and undoped AlN. FIG. 6D shows another view of the kt² or the overall efficiency of electromechanical coupling. It is slightly brighter on the high-Yb region, giving a preference to Yb>Y or Yb-rich material.

FIGS. 6E and 6F show the dielectric permittivity ε_{r,33} with all materials showing desirably low levels. The dielectric permittivity indicates how much voltage is needed to get a displacement field in the material. It is typically preferred to have a low level, so y=33%, z=17% (or y=17%, z=33%) is better than 25-25%. But the FoM is typically e_{31,f}/ε_{r,33}ⁿ; hence it is preferred to gain a 10× increase in e_{31,f} and sacrifice a mere 1.5× in ε_{r,33}.

FIGS. 6G and 6H show SCAN bandgap (calculated using the DFT meta-gga functional SCAN which is more accurate than the traditional PBE method). FIGS. 6G and 6H show that as doping increases—especially in Y—there is a risk of the bandgap lowering, and therefore reducing the breakdown voltage. An unobvious finding leads to a slight preference to Yb>Y.

FIG. 6I shows the speed of sound, relating to a thickness of a layer proportional to the speed of sound. This property indicates a feasible layer thickness in an acoustic component. FIG. 6J shows values of e_{31,f} vs. the permittivity for the materials in the Al—Y—Yb—N space.

There are several different ways of stacking Al, Y, and Yb within the wurtzite cell. A non-limiting example is shown in FIG. 7. FIG. 7 shows a 1:1 layered structure. The unit cell is shown in black lines and the wurtzite c-axis is visible in the vertical direction.

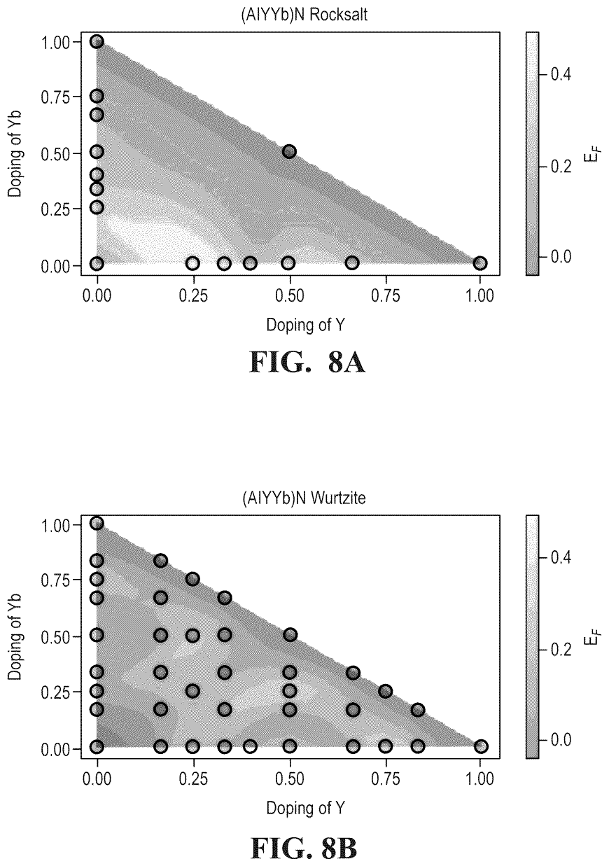

To avoid formation of the rocksalt structure discussed above, the formation energy E_{F} in eV/atom plots for the Al—Y—Yb system are shown in FIGS. 8A and 8B. The light color in FIG. 8A indicates inhibition of the rocksalt formation. As can be observed, once the total alloying is above 50%, there is a risk of rocksalt formation, although presence of Y may inhibit it. The lower the energy of formation, the higher the probability to result in the crystal type.

As described above, the e_{31,f} as well as the e_{31,f}²/ε_{r,33} are high for the AlYYbN materials which makes their use in piezoelectric MEMS applications advantageous, especially in actuators, e.g. micromirrors, micro-speakers, inertial sensor, ultrasound sensors, and sensors like microphones. To overcome the difference in e_{31,f} as compared to PZT, a double layer with opposing polarization directions may be used.

Also disclosed is an acoustic component, such as an acoustic sensor, comprising a substrate layer, a first electrode layer, an aluminum nitride piezoelectric layer, and a second electrode layer. The piezoelectric layer contains an aluminum nitride based piezoelectric material of formulas (I), (II), (III), or their combination.

In certain embodiments, the ultrasound component can be an acoustic sensor such as a microphone, piezoelectric transducer, micromirrors, micro-speakers, ultrasonic sensor, speaker, and/or acoustic emission sensor. Additionally, the MEMS devices disclosed herein can be incorporated in an actuator, an RF resonator, BAW resonator, inertial sensor, or RF filter. While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. A microelectromechanical systems (MEMS) device comprising:
a first electrode and a second electrode spaced apart from the first electrode by an aluminum nitride piezoelectric layer having a first material of formula (II): 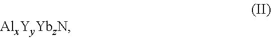
where x+y+z=1 and x is any number between 0.3 and 0.9.

2. The device of claim 1, wherein z>y.

3. The device of claim 1, wherein z=y.

4. The device of claim 1, wherein the material includes Al_{0.5}Y_{0.25}Yb_{0.25}N.

5. The device of claim 1, further comprising a second material of formula (I): 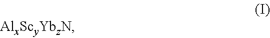
where x+y+z=1 and x is any number between 0.3 and 0.9.

6. The device of claim 1, further comprising a second material of formula (III): 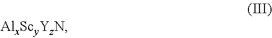
where x+y+z=1 and x is any number between 0.3 and 0.9.

7. The device of claim 1, wherein the first material has a c/a value between 1.3 and 1.5.

8. The device of claim 1, wherein the device is an ultrasonic transducer.

9. An acoustic component comprising:
a substrate layer;
a first electrode layer adjacent the substrate layer;
a second electrode layer spaced apart from the first electrode layer; and
an aluminum nitride based piezoelectric portion disposed between the first and second electrode layers and comprising a first material having a composition of formula (II): 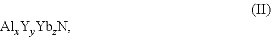
where x+y+z=1 and x is any number between 0.3 and 0.9.

10. The component of claim 9, wherein z>y.

11. The component of claim 9, wherein z=y.

12. The component of claim 9, wherein x is 0.3 to 0.55.

13. The component of claim 9, wherein the aluminum nitride based piezoelectric portion includes a layer having a first material of formula (II) with a gradient in ratio of Y:Yb, Al:Yb, or A:Y.

14. The component of claim 9, wherein the aluminum nitride based piezoelectric portion includes a first layer having a first material of formula (II) with a first ratio of Y:Yb and a second layer, discrete from the first layer, having a second material of formula (II) with a second ratio of Y:Yb, the first and second ratios being different.

15. A piezoelectric material deposit comprising:
a plurality of layers including a first material having a composition of formula (II): 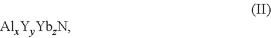
where x+y+z=1 and x is any number between 0.3 and 0.9,
at least one of the plurality of layers having a different x, y, or z values in comparison to at least another one of the plurality of layers.

16. The deposit of claim 15, wherein at least one of the plurality of layers further comprises a second material having a composition of formula (II): 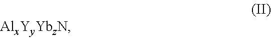
where x+y+z=1 and x is any number between 0.3 and 0.9.

17. The deposit of claim 15, wherein at least one of the plurality of layers further comprises a second material having a composition of formula (III): 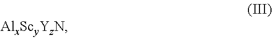
where x+y+z=1 and x is any number between 0.3 and 0.9.

18. The deposit of claim 15, wherein z>y.

19. The deposit of claim 15, wherein z=y.

20. The deposit of claim 15, wherein z=y, wherein the plurality of layers have a gradient in a ratio of Y:Yb, Al:Yb, or Al:Y.
